(19) United States
(12) Patent Application Publication
(10) Pub. No.: US 2024/0074154 A1
(43) Pub. Date: Feb. 29, 2024

(54) SEMICONDUCTOR MEMORY DEVICE AND METHOD OF FABRICATING THE SAME

(71) Applicant: Samsung Electronics Co., Ltd., Suwon-si (KR)

(72) Inventors: Seonhaeng LEE, Suwon-si (KR); SANGWOO PAE, Suwon-si (KR); NAMHYUN LEE, Suwon-si (KR)

(73) Assignee: Samsung Electronics Co., Ltd., Suwon-si (KR)

(21) Appl. No.: 18/126,395

(22) Filed: Mar. 25, 2023

(30) Foreign Application Priority Data
Aug. 23, 2022 (KR) 10-2022-0105740

(51) Int. Cl. H10B 12/00

(52) U.S. Cl. CPC H10B 12/34; H10B 12/053; H10B 12/09; H10B 12/315; H10B 12/50

(57) ABSTRACT

A semiconductor memory may include a substrate, a buried dielectric layer on the substrate and providing a first recess that extends in a first direction, a word line in the first recess of the buried dielectric layer, first and second source/drain patterns on opposite sides of the word line, a channel pattern between the word line and the first recess of the buried dielectric layer and contacting the first and second source/drain patterns, and a bit line electrically connected to the second source/drain pattern and extending in a second direction that intersects the first direction. The channel pattern includes vertical parts and a horizontal part connected to each other. The vertical parts are on opposite lateral surfaces of the word line. The horizontal part is below the word line.

### CROSS-REFERENCE TO RELATED APPLICATION(S)

This U.S. nonprovisional application claims priority under 35 U.S.C § 119 to Korean Patent Application No. 10-2022-0105740 filed on Aug. 23, 2022 in the Korean Intellectual Property Office, the disclosure of which is incorporated by reference herein in its entirety.

### BACKGROUND

The present inventive concepts relate to a semiconductor memory device and a method of fabricating the same, and more particularly, to a semiconductor memory device with improved electrical properties and a method of fabricating the same.

Semiconductor devices have an important role in the electronic industry because of their small size, multi-functionality, and/or low fabrication cost. Semiconductor devices have increasingly integrated with the development of electronic industry. Line widths of patterns of semiconductor devices are being reduced for high integration thereof. However, new exposure techniques and/or expensive exposure techniques are required for fineness of the patterns such that it is difficult to highly integrate semiconductor devices. Various studies have thus recently been conducted for new integration techniques.

### SUMMARY

Some embodiments of the present inventive concepts provide a semiconductor memory device with improved electrical properties and a method of fabricating the same.

The object of the present inventive concepts is not limited to the mentioned above, and other objects which have not been mentioned above will be clearly understood to those skilled in the art from the following description.

According to some embodiments of the present inventive concepts, a semiconductor memory device may include: a substrate; a buried dielectric layer on the substrate and providing a first recess that extends in a first direction; a word line in the first recess of the buried dielectric layer; first and second source/drain patterns on opposite sides of the word line; a channel pattern between the word line and the first recess of the buried dielectric layer, the channel pattern contacting the first and second source/drain patterns; and a bit line electrically connected to the second source/drain pattern and extending in a second direction that intersects the first direction. The channel pattern may include vertical parts and a horizontal part connected to each other. The vertical parts may be on opposite lateral surfaces of the word line. The horizontal part may be below the word line.

According to some embodiments of the present inventive concepts, a semiconductor memory device may include: a substrate that includes a cell array region and a peripheral circuit region; a buried dielectric layer on the substrate and including first recesses that extend in a first direction on the cell array region; word lines in corresponding first recesses of the buried dielectric layer; channel patterns between the buried dielectric layer and the word lines; first and second source/drain patterns on opposite sides of each of the word lines; bit lines that extend in a second direction intersecting the first direction on the first and second source/drain patterns, bit-line contacts that connect the second source/drain patterns to the bit lines; data storage patterns on the first source/drain patterns; storage contacts that connect the data storage patterns to the first source/drain patterns; and a peripheral transistor on the peripheral circuit region and on the buried dielectric layer. The channel patterns may be in contact with the first and second source/drain patterns.

According to some embodiments of the present inventive concepts, a method of fabricating a semiconductor memory device may include: preparing a substrate that includes a cell array region and a peripheral circuit region; forming a buried dielectric layer on the substrate; forming a recess by partially etching the buried dielectric layer on the cell array region; forming in the recess a word-line structure that includes a word line, a channel pattern, and a gate dielectric pattern; forming a channel layer on the buried dielectric layer on the peripheral circuit region; forming a gate pattern on the channel layer; forming first and second source/drain patterns on opposite sides of the word-line structure; and forming peripheral source/drain patterns on opposite sides of the gate pattern. The step of forming the first and second source/drain patterns and the step of forming the peripheral source/drain patterns may be performed at the same time.

### BRIEF DESCRIPTION OF THE DRAWINGS

FIG. 1 illustrates a plan view showing a semiconductor memory device according to some embodiments of the present inventive concepts.

FIGS. 2A and 2B illustrate cross-sectional views respectively taken along lines A-A′ and B-B′ of FIG. 1, showing a semiconductor memory device according to some embodiments of the present inventive concepts.

FIGS. 3A and 3B illustrate cross-sectional views respectively taken along lines A-A′ and B-B′ of FIG. 1, showing a semiconductor memory device according to some embodiments of the present inventive concepts.

FIGS. 4A, 4B, 5A, 5B, 6A, 6B, 7A, 7B, 8A, 8B, 9A, and 9B illustrate cross-sectional views showing a method of fabricating a semiconductor memory device according to some embodiments of the present inventive concepts.

FIGS. 4A, 5A, 6A, 7A, 8A, and 9A illustrate cross-sectional views taken along line A-A′ of FIG. 1 according to some embodiments.

FIGS. 4B, 5B, 6B, 7B, 8B, and 9B illustrate cross-sectional views taken along line B-B′ of FIG. 1 according to some embodiments.

FIGS. 10A, 10B, 11A, and 11B illustrate cross-sectional views showing a method of fabricating a semiconductor memory device according to some embodiments of the present inventive concepts.

FIGS. 10A and 11A illustrate cross-sectional views taken along line A-A′ of FIG. 1 according to some embodiments.

FIGS. 10B and 11B illustrate cross-sectional views taken along line B-B′ of FIG. 1 according to some embodiments.

### DETAIL PARTED DESCRIPTION OF EMBODIMENTS

The following will now describe some embodiments of the present inventive concepts with reference to the accompanying drawings. Like reference numerals may indicate like components throughout the description.

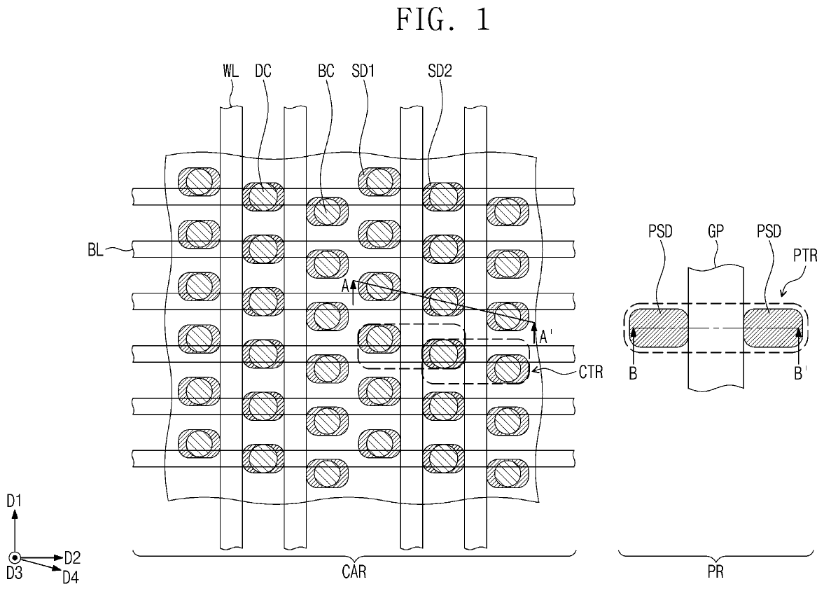

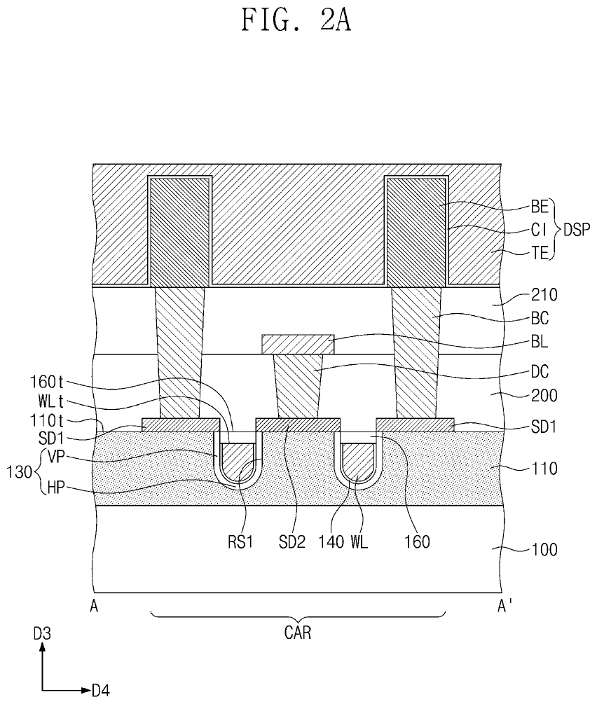

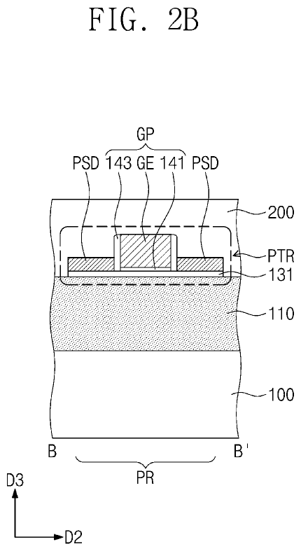

FIG. 1 illustrates a plan view showing a semiconductor memory device according to some embodiments of the present inventive concepts. FIGS. 2A and 2B illustrate cross-sectional views respectively taken along lines A-A′ and B-B′ of FIG. 1, showing a semiconductor memory device according to some embodiments of the present inventive concepts.

Referring to FIGS. 1, 2A, and 2B, a semiconductor substrate 100 may be provided. The semiconductor substrate 100 may include a silicon (Si) substrate, a silicon-germanium (SiGe) substrate, or a silicon-on-insulator (SOI) substrate.

A buried dielectric layer 110 may be provided on the semiconductor substrate 100. The buried dielectric layer 110 may provide a first recess RS1 that is formed by removing a portion of a top surface 110t thereof. The first recess RS1 may have a width less than a depth of the first recess RS1. The buried dielectric layer 110 may include or be formed of a dielectric material, such as SiO₂, SiON, HfSiON, HfO₂, SiCN, SiOCN, and SiN.

The semiconductor substrate 100 may include a cell array region CAR and a peripheral circuit region PR. The cell array region CAR and the peripheral circuit region PR may be spaced apart from each other in a second direction D2.

Referring to FIGS. 1 and 2A, cell transistors CTR may be provided on the cell array region CAR of the semiconductor substrate 100. Each of the cell transistors CTR may include a word line WL, a first source/drain pattern SD1, and a second source/drain pattern SD2. When viewed in plan, the cell transistors CTR may be two-dimensionally arranged in a first direction D1 and the second direction D2 that interests the first direction D1. The cell transistors CTR may be arranged extending in a fourth direction D4. The cell transistors CTR adjacent to each other in the fourth direction D4 may share the second source/drain pattern SD2.

Each of word-line structures may include the word line WL, a gate dielectric pattern 140, a channel pattern 130, and a gate capping pattern 160. Each of word-line structures may be buried in the buried dielectric layer 110, and may extend in the first direction D1 while running across the cell transistors CTR. For example, the channel pattern 130, the gate dielectric pattern 140, the word line WL, and the gate capping pattern 160 may be stacked in the first recess R1. The word-line structures may be spaced apart from each other in the second direction D2.

The word line WL may be provided in the first recess RS1 of the buried dielectric layer 110. When viewed in plan, the word line WL may extend in the first direction D1 to run across the cell transistor CTR. For example, the word line WL may fill a lower portion of the first recess RS1 of the buried dielectric layer 110. The word line WL may have a top surface WLt located lower than the top surface 110t of the buried dielectric layer 110. In this configuration, the word line WL may be buried in the buried dielectric layer 110. The word line WL may be spaced apart in a third direction D3 from the semiconductor substrate 100.

The word line WL may include or be formed of a metallic material, such as tungsten (W), copper (Cu), titanium (Ti), or tantalum (Ta).

The channel pattern 130 may be provided between the word line WL and the buried dielectric layer 110. The channel pattern 130 may include vertical parts VP and a horizontal part HP. The vertical and horizontal parts VP and HP of the channel pattern 130 may have their uniform thickness. The vertical parts VP of the channel pattern 130 may have their shapes that extend in the third direction D3. The vertical parts VP of the channel pattern 130 may be positioned on opposite lateral surfaces of the word line WL.

The horizontal part HP of the channel pattern 130 may be positioned below the word line WL. The horizontal part HP of the channel pattern 130 may connect to each other lower portions of the vertical parts VP of the channel pattern 130. For example, the channel pattern 130 may have a shape that surrounds the word line WL. The horizontal part HP of the channel pattern 130 may have a shape that is concave toward the word line WL, but the present inventive concepts are not limited thereto.

The channel pattern 130 may have a top surface located at a higher level than that of the top surface WLt of the word line WL. The top surface of the channel pattern 130 may be positioned on the same plane as that of the top surface 110t of the buried dielectric layer 110. For example, the top surface of the channel pattern 130 may be coplanar with the top surface 110t of the buried dielectric layer 110.

The channel pattern 130 may include or be formed of undoped silicon (Si) or undoped silicon-germanium (SiGe). Alternatively, the channel pattern 130 may have a multi-layered structure including different materials.

As the word line WL and the channel pattern 130 are buried in the buried dielectric layer 110, a gate length may be relatively greater than that of a planar transistor. In addition, as the buried dielectric layer 110 is positioned between the semiconductor substrate 100 and the word line WL and between the semiconductor substrate 100 and the channel pattern 130, it may be possible to reduce the occurrence of leakage current caused by electrical interference between the word lines WL. Accordingly, a semiconductor memory device may increase in performance.

The gate dielectric pattern 140 may be provided between the word line WL and the channel pattern 130. The gate dielectric pattern 140 may be in contact with the word line WL and the channel pattern 130. The gate dielectric pattern 140 may have a top surface coplanar with the top surface WLt of the word line WL. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

The gate dielectric pattern 140 may include or be formed of a high-k dielectric layer, a silicon oxide layer, a silicon nitride layer, a silicon oxynitride layer, or a combination thereof. For example, the high-k dielectric layer may include at least one selected from hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

The gate capping pattern 160 may be provided on the word line WL and the gate dielectric pattern 140. The vertical parts VP of the channel pattern 130 may be positioned on opposite sidewalls of the gate capping pattern 160. The gate capping pattern 160 may have a top surface coplanar with the top surface of the channel pattern 130 and the top surface 110t of the buried dielectric layer 110.

The gate capping pattern 160 may separate the word line WL from the first and second source/drain patterns SD1 and SD2 which will be discussed below. The gate capping pattern 160 may include or be formed of silicon nitride or silicon oxynitride.

The first and second source/drain patterns SD1 and SD2 may be provided on the buried dielectric layer 110 and opposite sides of each of the word lines WL. The second source/drain pattern SD2 may be disposed between neighboring word lines WL. The first source/drain pattern SD1 may be disposed spaced apart from the second source/drain pattern SD2. For example, the word line WL may be positioned between the first source/drain pattern SD1 and the second source/drain pattern SD2.

The first and second source/drain patterns SD1 and SD2 may be in contact with portions of the channel pattern 130. For example, the first and second source/drain patterns SD1 and SD2 may be in contact with and electrically connected to top surfaces of the vertical parts VP of the channel pattern 130.

The first source/drain pattern SD1 may correspond to a drain of the cell transistor CTR. The second source/drain pattern SD2 may correspond to a source of the cell transistor CTR. The first and second source/drain patterns SD1 and SD2 may include impurities having a conductivity type different from that of the semiconductor substrate 100. Each of the first and second source/drain patterns SD1 and SD2 may include or be formed of silicon (Si) or silicon-germanium (SiGe).

Differently from that shown, portions or entireties of the first and second source/drain patterns SD1 and SD2 may be provided in the buried dielectric layer 110. For example, the first and second source/drain patterns SD1 and SD2 may also be buried in the buried dielectric layer 110. In this case, the first and second source/drain patterns SD1 and SD2 may have their bottom surfaces lower than the top surface 110t of the buried dielectric layer 110. The first and second source/drain patterns SD1 and SD2 may be in contact with and electrically connected to lateral surfaces of the vertical parts VP of the channel pattern 130.

A first interlayer dielectric layer 200 may be provided on the buried dielectric layer 110, the word-line structures, and the first and second source/drain patterns SD1 and SD2. The first interlayer dielectric layer 200 may cover the first and second source/drain patterns SD1 and SD2 and the word-line structures. The first interlayer dielectric layer 200 may include or be formed of one or more of silicon oxide, silicon nitride, and silicon oxynitride.

A bit line BL may be disposed on the first interlayer dielectric layer 200. When viewed in vertical section, the bit line BL may be disposed on the second source/drain pattern SD2. The bit line BL may extend in the second direction D2 on the semiconductor substrate 100, while running across the word line WL.

The bit line BL may include a conductive material, such as polysilicon, impurity-doped polysilicon, and a metallic material. The metallic material may include or be formed of tungsten (W), copper (Cu), titanium (Ti), or tantalum (Ta). Alternatively, the bit line BL may have a multi-layered structure. The multi-layered structure may include or be formed of one or more of a polysilicon pattern, a silicide pattern, a metal pattern, and a hardmask pattern.

Although not shown, bit-line spacers may be provided on opposite sidewalls of the bit line BL. The bit-line spacers may extend in the second direction D2 along the bit line BL. The bit-line spacers may include or be formed of one or more of silicon oxide and silicon nitride.

A bit-line contact DC may be provided to penetrate the first interlayer dielectric layer 200. When viewed in plan, the bit-line contact DC may be disposed between storage contacts BC which will be discussed below. When viewed in vertical section, the bit-line contact DC may be positioned between the bit line BL and the second source/drain pattern SD2. The bit-line contact DC may be in contact with the bit line BL and the second source/drain pattern SD2. In some embodiments, the bit-line contact DC may have a bottom surface located below a top surface of the second source/drain pattern SD2. The bit-line contact DC may electrically connect the second source/drain pattern SD2 to the bit line BL.

The bit-line contact DC may have a width that decreases in a direction from top toward bottom surfaces thereof. Alternatively, the bit-line contact DC may have a width that is substantially the same as at top and bottom surfaces thereof. The bit-line contact DC may include at least one selected from doped semiconductor materials (e.g., doped silicon, etc.), metals (e.g., tungsten, aluminum, titanium, and/or tantalum), conductive metal nitrides (e.g., titanium nitride, tantalum nitride, and/or tungsten nitride), and metal-semiconductor compounds (e.g., metal silicide).

A second interlayer dielectric layer 210 may be provided on the first interlayer dielectric layer 200. The second interlayer dielectric layer 210 may cover the bit line BL. The second interlayer dielectric layer 210 may include or be formed of one or more of silicon oxide, silicon nitride, and silicon oxynitride. The second interlayer dielectric layer 210 may include a different material from that of the first interlayer dielectric layer 200.

One or more data storage patterns DSP may be provided on the second interlayer dielectric layer 210.

For example, the data storage pattern DSP may be a capacitor. In this case, the data storage pattern DSP may include a bottom electrode BE, a top electrode TE, and a dielectric layer CI. The dielectric layer CI may be positioned between the top electrode TE and the bottom electrode BE. The bottom electrode BE may have a pillar shape or a cylindrical shape. When viewed in plan, the bottom electrode BE may be disposed in a honeycomb shape or a zigzag shape.

Alternatively, the data storage patterns DSP may be a variable resistance pattern that is switched from one to the other of its two resistance states by an applied electrical pulse. For example, the data storage patterns DSP may include a phase change material whose crystalline state is changed based on an amount of current, perovskite compounds, transition metal oxide, magnetic materials, ferromagnetic materials, or antiferromagnetic materials.

Storage contacts BC may be provided to penetrate the first and second interlayer dielectric layers 200 and 210. The storage contacts BC may be spaced apart from each other in the fourth direction D4. When viewed in vertical section, the storage contacts BC may be positioned between the first source/drain patterns SD1 and the data storage patterns DSP. The storage contacts BC may be in contact with the first source/drain patterns SD1 and the bottom electrode BE of the data storage patterns DSP. In some embodiments, the storage contacts BC may have their bottom surfaces located lower than top surfaces of the first source/drain patterns SD1. The storage contacts BC may electrically connect the first source/drain patterns SD1 to the bottom electrode BE of the data storage patterns DSP. When viewed in plan, the storage contacts BC may be disposed in a honeycomb shape or a zigzag shape.

The storage contact BC may have a width that decreases in a direction from top toward bottom surfaces thereof. Alternatively, the storage contact BC may have a width that is substantially the same as at top and bottom surfaces thereof. The storage contact BC may include at least one selected from doped semiconductor materials (e.g., doped silicon, etch), metals (e.g., tungsten, aluminum, titanium, and/or tantalum), conductive metal nitrides (e.g., titanium nitride, tantalum nitride, and/or tungsten nitride), and metal-semiconductor compounds (e.g., metal silicide).

Although not shown, a landing pad may be provided between the storage contact BC and the data storage pattern DSP. The storage contact BC and the data storage pattern DSP may be entirely or partially in contact with the landing pad. The landing pad may be electrically connected to the storage contact BC and the data storage pattern DSP.

Referring to FIGS. 1 and 2B, a peripheral transistor PTR may be provided on the peripheral circuit region PR of the semiconductor substrate 100. The peripheral transistor PTR may be, for example, one or more of NMOS and PMOS transistors. The peripheral transistor PTR may include peripheral source/drain patterns PSD, a channel layer 131, and a gate pattern GP.

The channel layer 131 may be provided on the buried dielectric layer 110. The channel layer 131 may have a size substantially the same as that of the peripheral transistor PTR. Different from the channel pattern 130 on the cell array region CAR, the channel layer 131 may have a planar shape. For example, the peripheral transistor PTR may be a planar transistor. The channel layer 131 may be formed simultaneously with the channel pattern 130 on the cell array region CAR. Therefore, the channel layer 131 may include or be formed of the same material as that of the channel pattern 130 and may have the same thickness as that of the channel pattern 130.

The peripheral source/drain patterns PSD may be provided on the channel layer 130. The gate pattern GP may be positioned between the peripheral source/drain patterns PSD. For example, one of the peripheral source/drain patterns PSD may be a source of the peripheral transistor PTR. Another of the peripheral source/drain patterns PSD may be a drain of the peripheral transistor PTR. The peripheral source/drain patterns PSD may include or be formed of the same material as that of the first and second source/drain patterns SD1 and SD2.

The gate pattern GP may be provided on the channel layer 131 and positioned between the peripheral source/drain patterns PSD. The gate pattern GP may include a gate dielectric layer 141, a gate electrode GE, and gate spacers 143. The gate electrode GE may be provided on the gate dielectric layer 141. The gate spacers GS may be provided on opposite sidewalls of the gate electrode GE.

The gate electrode GE may include or be formed of the same material as that of the word line WL. The gate dielectric spacer 141 may include or be formed of the same material as that of the gate dielectric pattern 140 in the cell array region CAR. The gate spacers 143 may include or be formed of one or more of silicon oxide, silicon nitride, and silicon oxynitride.

A first interlayer dielectric layer 200 may be provided on the buried dielectric layer 110 and the peripheral transistor PTR. The first interlayer dielectric layer 200 may cover the peripheral transistor PTR.

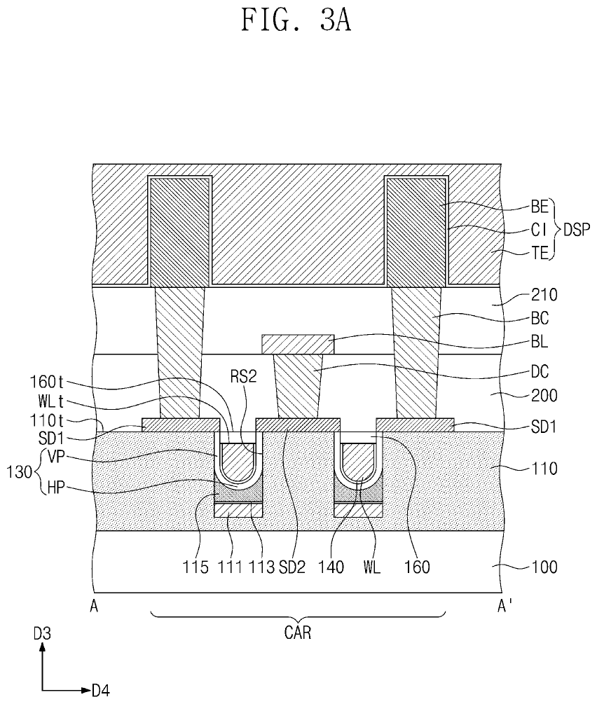

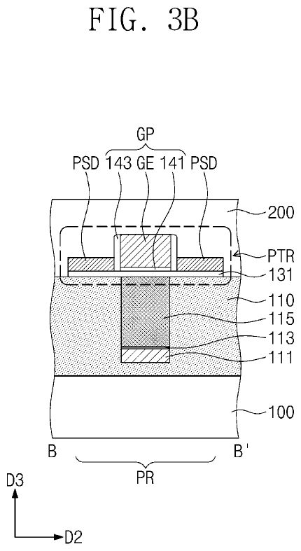

FIGS. 3A and 3B illustrate cross-sectional views respectively taken along lines A-A′ and B-B′ of FIG. 1, showing a semiconductor memory device according to some embodiments of the present inventive concepts.

For convenience of description, omission will be made to avoid a repetitive explanation of the same components discussed with reference to FIGS. 1, 2A and 2B, and a difference thereof will be described in detail.

Referring to FIGS. 3A and 3B, a buried dielectric layer 110 may be provided on the cell array region CAR and the peripheral circuit region PR of the semiconductor substrate 100. The buried dielectric layer 110 may provide a second recess RS2 that is formed by removing a portion of a top surface 110t thereof. The second recess RS2 may have a width less than a depth of the second recess RS2. A conductive line 111, a protection layer 113, and a dielectric pattern 115 may be provided in the buried dielectric layer 110. The conductive line 111, the protection layer 113, and the dielectric pattern 115 may be stacked in the foregoing sequence. For example, the conductive line 111, the protection layer 113, the dielectric pattern 115, and the word-line structure may be stacked in the second recess RS2.

Alternatively, none of the conductive line 111, the protection layer 113, and the dielectric pattern 115 may be provided on the peripheral circuit region PR of the semiconductor substrate 100.

Referring to FIG. 3A, on the cell array region CAR, the conductive line 111 may be positioned below the word line WL in the buried dielectric layer 110. Likewise the word line WL, the conductive line 111 may extend in the first direction D1. The conductive line 111 may be parallel to and spaced apart in the third direction D3 from the word line WL. The conductive line 111 may have a width the same as that of the word-line structure in the second direction D2. For example, the conductive line 111 may have a width the same as that of the channel pattern 130 in the second direction D2.

The conductive line 111 may include or be formed of a conductive material, such as polysilicon, impurity-doped polysilicon, and metallic materials. The metallic material may include tungsten (W), copper (Cu), titanium (Ti), or tantalum (Ta).

The protection layer 113 may be positioned on the conductive line 111. The protection layer 113 may be in contact with the conductive line 111. The protection layer 113 may be spaced apart in the third direction D3 from the word line WL. The protection layer 113 may prevent oxidation of the metallic material included in the conductive line 111. Therefore, when the conductive line 111 includes no metallic material, the protection layer 113 may be omitted. The protection layer 113 may include or be formed of one or more of silicon nitride and silicon oxynitride that contain nitrogen (N).

When viewed in vertical section, a central axis of the conductive line 111 and the protection layer 113 may overlap that of the word line WL, but the present inventive concepts are not limited thereto.

The dielectric pattern 115 may be positioned between the protection layer 113 and the word-line structure. The dielectric pattern 115 may cause the conductive line 111 and the word-line structure to separate from each other in the third direction D3. The dielectric pattern 115 may include or be formed of the same material as that of the buried dielectric layer 110. The dielectric pattern 115 may include or be formed of a dielectric material, such as SiO₂, SiON, HfSiON, HfO₂, SiCN, SiOCN, and SiN.

Referring to FIG. 3B, on the peripheral circuit region PR, the conductive line 111 and the protection layer 113 may be positioned below the gate pattern GP. The conductive line 111 may be spaced apart in the third direction D3 from the gate pattern GP and the channel layer 131. For example, the dielectric pattern 115 may be positioned between the conductive line 111 and the gate pattern GP. The conductive line 111 may have a width the same as that of the gate electrode GE.

Because a bias voltage is applied through the conductive line 111, a threshold voltage may be controlled by creating a substrate effect only in a specific word line WL and a specific peripheral transistor PTR. For example, no bias voltage may be applied to an entirety of the semiconductor substrate 100, and thus a substrate effect may be improved. Accordingly, it may be possible to minimize a capacitor leakage current resulting from an electric field of an adjacent word line WL on the cell array region CAR.

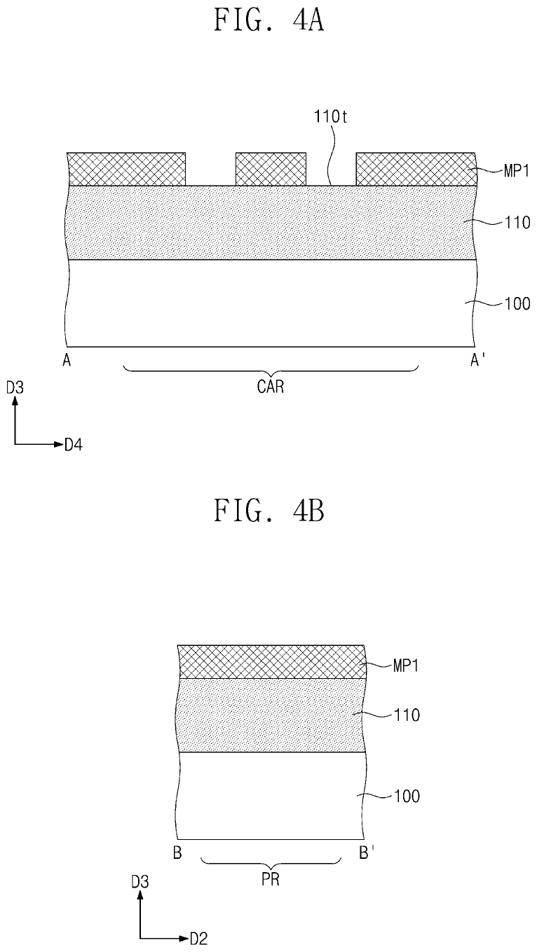

FIGS. 4A, 4B, 5A, 5B, 6A, 6B, 7A, 7B, 8A, 8B, 9A, and 9B illustrate cross-sectional views showing a method of fabricating a semiconductor memory device according to some embodiments of the present inventive concepts. FIGS. 4A, 5A, 6A, 7A, 8A, and 9A illustrate cross-sectional views taken along line A-A′ of FIG. 1 according to some embodiments. FIGS. 4B, 5B, 6B, 7B, 8B, and 9B illustrate cross-sectional views taken along line B-B′ of FIG. 1 according to some embodiments.

Referring to FIGS. 4A and 4B, a semiconductor substrate 100 may include a cell array region CAR and a peripheral circuit region PR. A buried dielectric layer 110 may be formed on the cell array region CAR and the peripheral circuit region PR of the semiconductor substrate 100.

The buried dielectric layer 110 may be formed by an oxidation process. The oxidation process may include one or more of a thermal oxidation process, a dry oxidation process, and a wet oxidation process.

First mask patterns MP1 may be formed on the buried dielectric layer 110. When viewed in plan as shown in FIG. 1, on the cell array region CAR, the first mask patterns MP1 may extend in a first direction D1 and may be spaced apart from each other in a second direction D2. Therefore, the buried dielectric layer 110 may be partially exposed on a top surface 110t thereof. An interval between the first mask patterns MP1 may be the same as a width of a word-line structure which will be discussed below.

Alternatively, on the peripheral circuit region PR, the first mask pattern MP1 may be a single layer. For example, the first mask pattern MP1 may not expose the top surface 110t of the buried dielectric layer 110.

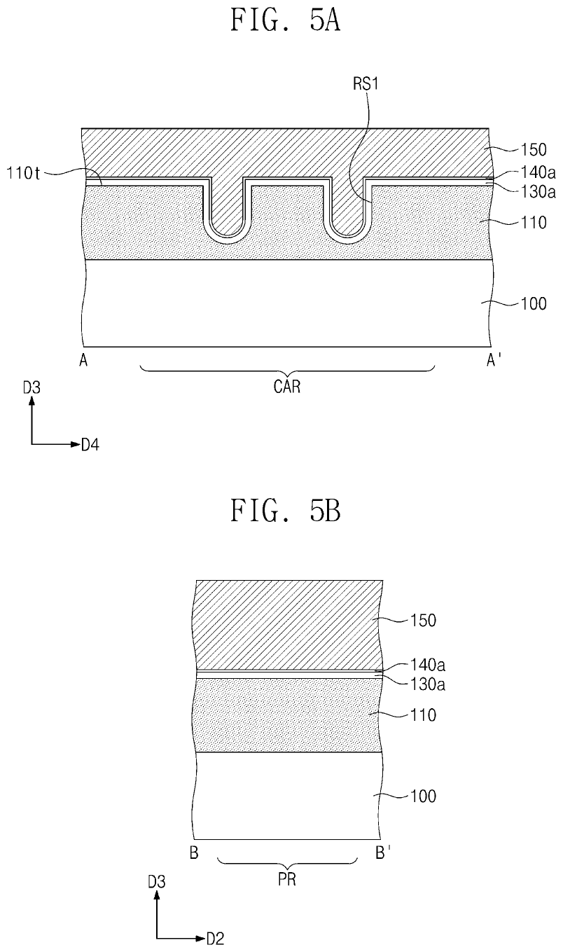

Referring to FIGS. 5A and 5B, an anisotropic etching process may be performed in which the first mask pattern MP1 is used as a mask. On the cell array region CAR, the top surface 110t of the buried dielectric layer 110 may be partially removed to form a first recess RS1. For example, the first recess RS1 may be formed by partially etching the buried dielectric layer 110 on the cell array region CAR. On the peripheral circuit region PR, the first recess RS1 may not be formed in the buried dielectric layer 110.

Afterwards, a preliminary channel layer 130a and a preliminary gate dielectric layer 140a may be conformally formed on the buried dielectric layer 110. On the cell array region CAR, the preliminary channel layer 130a and the preliminary gate dielectric layer 140a may cover the first recess RS1 of the buried dielectric layer 110.

A deposition process may be performed to form the preliminary channel layer 130a and the preliminary gate dielectric layer 140a. The deposition process may include one or more of chemical vapor deposition (CVD), physical vapor deposition (PVD), and atomic layer deposition (ALD).

The preliminary channel layer 130a may include undoped silicon (Si) or undoped silicon-germanium (SiGe). The preliminary gate dielectric layer 140a may include a high-k dielectric layer, a silicon oxide layer, a silicon nitride layer, a silicon oxynitride layer, or a combination thereof.

Thereafter, a conductive layer 150 may be formed on the preliminary gate dielectric layer 140a. A deposition process may be performed to form the conductive layer 150. The first recess RS1 of the buried dielectric layer 110 may be formed only on the cell array region CAR. Therefore, when the conductive layer 150 is formed by a deposition process, the conductive layer 150 may be first formed in the first recess RS1 on the cell array region CAR. A thickness, which is measured from the top surface 110t of the buried dielectric layer 110, of the conductive layer 150 may be different between the cell array region CAR and the peripheral circuit region PR. For example, a thickness of the conductive layer 150 on the peripheral circuit region PR may be greater than that of the conductive layer 150 on the cell array region CAR.

Alternatively, a height of the conductive layer 150 may be the same between the cell array region CAR and the peripheral circuit region PR. In this case, on the peripheral circuit region PR, a mask layer (not shown) may be separately formed on the conductive layer 150.

The conductive layer 150 may include a metallic material, such as tungsten (W), copper (Cu), titanium (Ti), or tantalum (Ta).

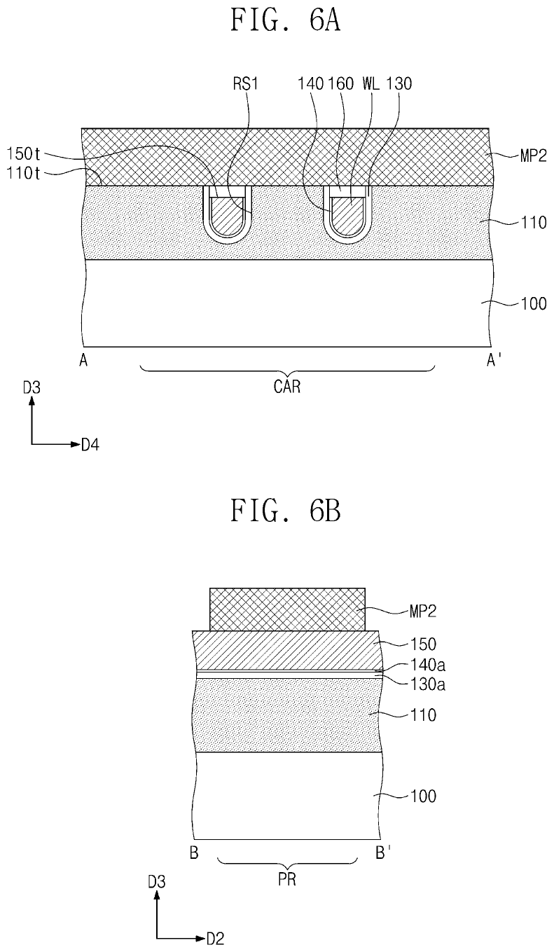

Referring to FIGS. 6A and 6B, a planarization process may be performed on the conductive layer 150. The planarization process may be simultaneously performed on both of the cell array region CAR and the peripheral circuit region PR. The planarization process may include one or more of a chemical mechanical polishing (CMP) process or an etch-back process.

On the cell array region CAR, the planarization process may be performed until a top surface 150t of the conductive layer 150 becomes lower than the top surface 110t of the buried dielectric layer 110. The planarization process may convert the conductive layer 150 into a word line WL. In addition, a portion of the preliminary channel layer 130a on the buried dielectric layer 110 and a portion of the preliminary gate dielectric layer 140a on the buried dielectric layer 110 may also be removed to form a channel pattern 130 and a gate dielectric pattern 140. After that, a gate capping pattern 160 may be formed on the word line WL and the gate dielectric pattern 140.

Because the thickness of the conductive layer 150 on the peripheral circuit region PR is greater than that of the conductive layer 150 on the cell array region CAR, even when the planarization process is simultaneously performed on both of the cell array region CAR and the peripheral circuit region PR, the conductive layer 150 may remain on the peripheral circuit region PR. Therefore, the planarization process may cause the conductive layer 150 to have a reduced height on the peripheral circuit region PR.

Afterwards, a second mask pattern MP2 may be formed. On the peripheral circuit region PR, the second mask pattern MP2 may have a size the same as that of a channel layer 131 which will be discussed below. Unlike on the peripheral circuit region PR, on the cell array region CAR, the second mask pattern MP2 may be a single layer. For example, the second mask pattern MP2 may cover the word-line structure and the buried dielectric layer 110.

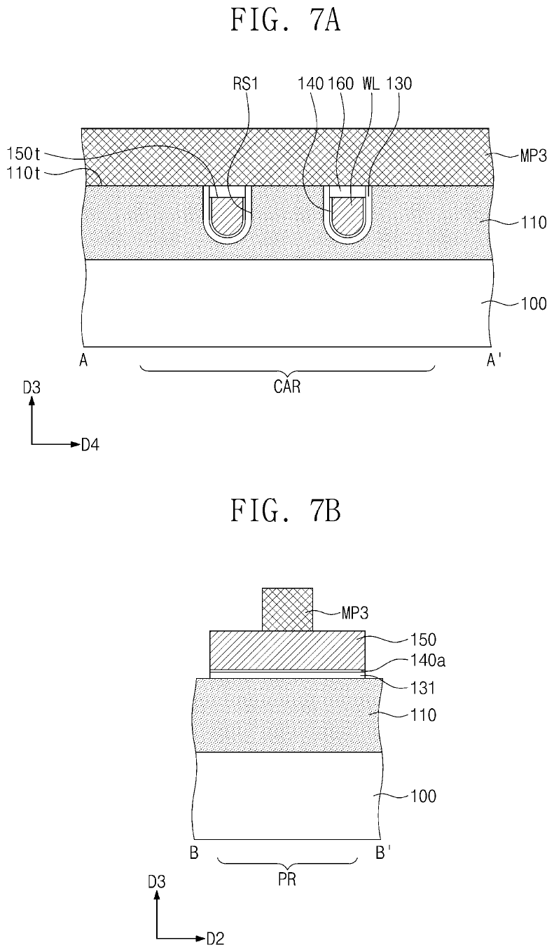

Referring to FIGS. 7A and 7B, an anisotropic etching process may be performed in which the second mask pattern MP2 is used as a mask. The etching process may have an etch selectivity with respect to the buried dielectric layer 110.

On the peripheral circuit region PR, the etching process may partially remove the conductive layer 150, the preliminary gate dielectric layer 140a, and the preliminary channel layer 130a. In this step, the etching process may convert the preliminary channel layer 130a into a channel layer 131.

On the cell array region CAR, the second mask pattern MP2 may protect the buried dielectric layer 110 and the word-line structure from the etching process.

After the etching process, an ashing process may be performed to remove a remaining second mask pattern MP2.

After that, a third mask pattern MP3 may be formed. On the peripheral circuit region PR, the third mask pattern MP3 may have a size the same as that of a gate electrode GE which will be discussed below. Unlike on the peripheral circuit region PR, on the cell array region CAR, the third mask pattern MP3 may be a single layer. For example, the third mask pattern MP3 may cover the word-line structure and the buried dielectric layer 110.

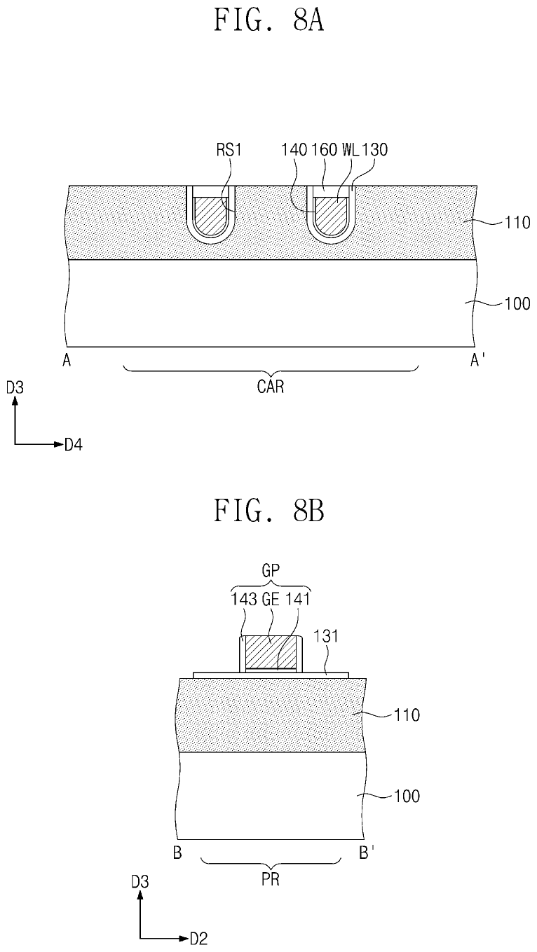

Referring to FIGS. 8A and 8B, an anisotropic etching process may be performed in which the third mask pattern MP3 is used as a mask. The etching process may have an etch selectivity with respect to the channel layer 131.

On the peripheral circuit region PR, the etching process may partially remove the conductive layer 150 and the preliminary gate dielectric layer 140a. In this step, the etching process may convert the conductive layer 150 into a gate electrode GE, and may also convert the preliminary gate dielectric layer 140a into a gate dielectric layer 141.

Unlike on the peripheral circuit region PR, on the cell array region CAR, the third mask pattern MP3 may protect the buried dielectric layer 110 and the word-line structure from the etching process.

After the etching process, an ashing process may be performed to remove a remaining third mask pattern MP3.

Thereafter, on the peripheral circuit region PR, a gate spacer layer (not shown) may be conformally formed, and then an anisotropic etching process may be performed. The etching process may convert the gate spacer layer into gate spacers 143. Therefore, on the peripheral circuit region PR, a gate pattern GP may be formed which includes the gate dielectric layer 141, the gate electrode GE, and the gate spacers 143.

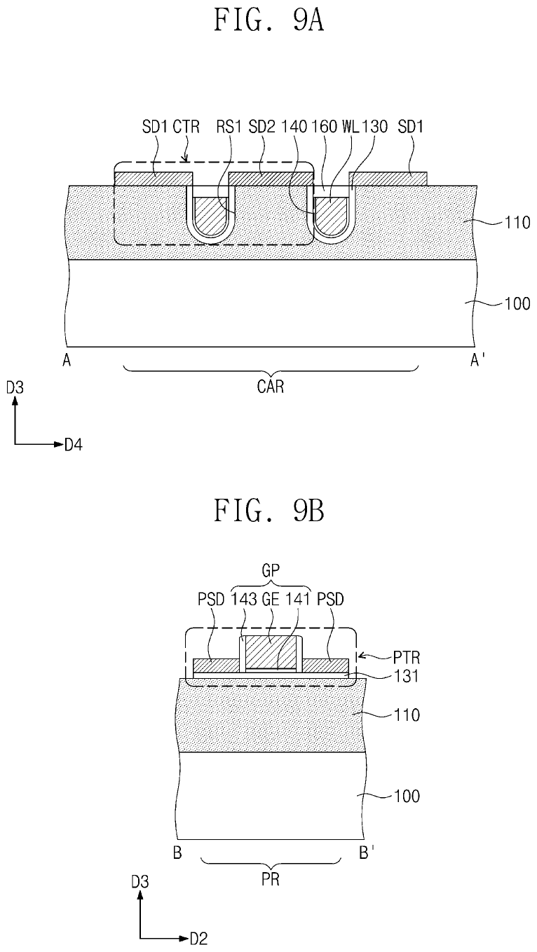

Referring to FIGS. 9A and 9B, first and second source/drain patterns SD1 and SD2 may be formed on the cell array region CAR. The formation of the first and second source/drain patterns SD1 and SD2 may include forming semiconductor patterns (not shown) and performing an ion implantation process on the semiconductor patterns. Peripheral source/drain patterns PSD may be formed on the peripheral circuit region PR. The formation of the peripheral source/drain patterns PSD may be the same as or similar to the formation of the first and second source/drain patterns SD1 and SD2.

When viewed in plan as shown in FIG. 1, the semiconductor patterns may be formed to correspond to the first and second source/drain patterns SD1 and SD2 on the cell array region CAR and to the peripheral source/drain patterns PSD on the peripheral circuit region PR. For example, the semiconductor patterns may be positioned on opposite sides of the word line WL on the cell array region CAR and on opposite sides of the gate pattern GP on the peripheral circuit region PR. A lithography process and an etching process may be performed to form the semiconductor patterns.

Afterwards, the semiconductor patterns may undergo an ion implantation process to form the first and second source/drain patterns SD1 and SD2 and the peripheral source/drain patterns PSD. Therefore, on the cell array region CAR, a cell transistor CTR may be formed which includes the word line WL, the channel pattern 130, and the first and second source/drain patterns SD1 and SD2. In addition, on the peripheral circuit region PR, a peripheral transistor PTR may be formed which includes the gate pattern GP, the channel layer 131, and the peripheral source/drain patterns PSD. The ion implantation process may be simultaneously performed on both of the cell array region CAR and the peripheral circuit region PR, but the present inventive concepts are not limited thereto.

In a method of fabricating a semiconductor memory device according to some embodiments of the present inventive concepts, the preliminary channel layer 130a, the preliminary gate dielectric layer 140a, and the conductive layer 150 may be formed at the same time on the cell array region CAR and the peripheral circuit region PR. In addition, the first and second source/drain patterns SD1 and SD2 and the peripheral source/drain patterns PSD may be formed at the same time. Therefore, it may be possible to simplify a fabrication process and to decrease a manufacturing cost of the semiconductor memory device.

Referring back to FIGS. 2A and 2B, a first interlayer dielectric layer 200 may be formed on the cell array region CAR and the peripheral circuit region PR.

On the cell array region CAR, a bit-line contact DC may be formed which penetrates the first interlayer dielectric layer 200. The bit-line contact DC may be connected to the second source/drain pattern SD2 on the cell array region CAR. A bit line BL may be formed on the bit-line contact DC and the first interlayer dielectric layer 200. The bit line BL may be connected to the bit-line contact DC.

After that, a second interlayer dielectric layer 210 may be formed on the semiconductor substrate 100. The second interlayer dielectric layer 210 may cover the peripheral transistor PTR on the peripheral circuit region PR. On the cell array region CAR, storage contacts BC may be formed to penetrate the first and second interlayer dielectric layers 200 and 210. The storage contacts BC may be connected to the first source/drain patterns SD1.

On the cell array region CAR, data storage patterns DSP may be formed on the storage contacts BC. For example, bottom electrodes BE may be formed on the storage contacts BC. A dielectric layer CI may be formed to conformally cover the bottom electrodes BE and the second interlayer dielectric layer 210. Afterwards, a top electrode TE may be formed on the dielectric layer CI. Thus, the data storage patterns DSP may be capacitors.

For another example, the data storage patterns DSP may include a phase change material, a variable resistance material, or a magnetic tunnel junction pattern.

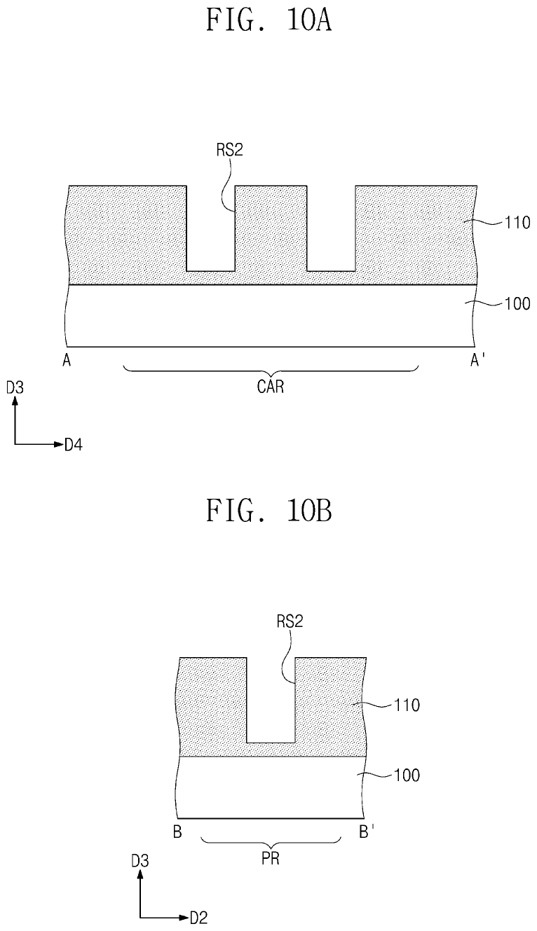

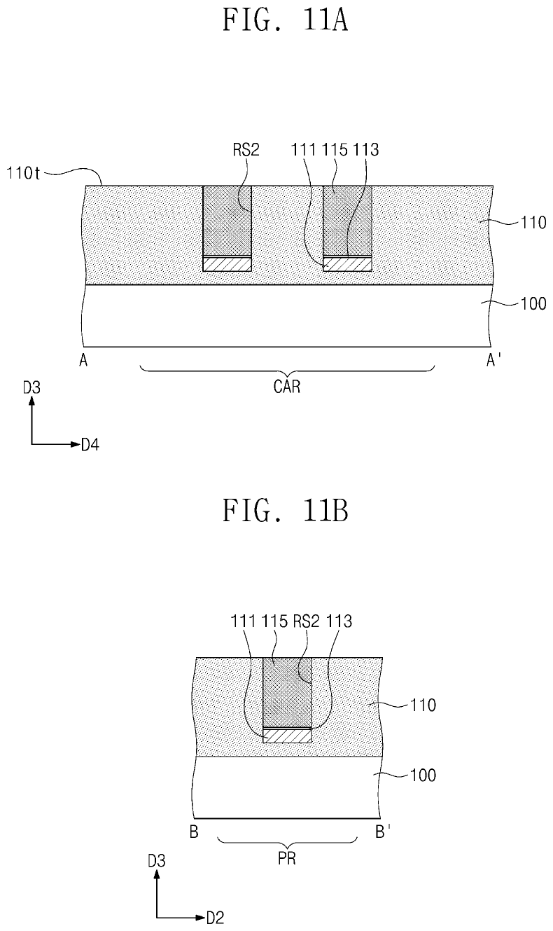

FIGS. 10A, 10B, 11A, and 11B illustrate cross-sectional views showing a method of fabricating a semiconductor memory device according to some embodiments of the present inventive concepts. FIGS. 10A and 11A illustrate cross-sectional views taken along line A-A′ of FIG. 1 according to some embodiments. FIGS. 10B and 11B illustrate cross-sectional views taken along line B-B′ of FIG. 1 according to some embodiments.

For convenience of description, omission will be made to avoid a repetitive explanation of the same components discussed with reference to FIGS. 4A, 4B, 5A, 5B, 6A, 6B, 7A, 7B, 8A, 8B, 9A, and 9B, and a difference thereof will be described in detail.

Referring to FIGS. 10A and 10B, a buried dielectric layer 110 may be formed on the semiconductor substrate 100. The buried dielectric layer 110 may be formed by an oxidation process. A mask pattern (not shown) may be formed on the buried dielectric layer 110.

An anisotropic etching process using the mask pattern may be performed to form a second recess RS2 in the buried dielectric layer 110. The second recess RS2 of each of FIGS. 10A and 10B may correspond to the second recess RS2 of each of FIGS. 3A and 3B, respectively. When viewed in plan, on the cell array region CAR, the second recess RS2 may extend in the first direction D1 and may be spaced apart from each other in the second direction D2.

On the cell array region CAR, the second recess RS2 may have a width the same as that of a word-line structure which will be discussed below. On the peripheral circuit region PR, the second recess RS2 may have a width the same as that of a gate electrode GE which will be discussed below. For example, the second recess RS2 may have a different size between the cell array region CAR and the peripheral circuit region PR.

The second recess RS2 may have a tetragonal shape, a circular shape, or a U shape, but the present inventive concepts are not limited thereto.

Referring to FIGS. 11A and 11B, a conductive line 111, a protection layer 113, and a dielectric pattern 115 may be formed in the second recess RS2 of the buried dielectric layer 110. The protection layer 113 may be formed on the conductive line 111, and the dielectric pattern 115 may be formed on the protection layer 113.

For example, the conductive line 111 and the protection layer 113 may fill a lower portion of the second recess RS2 of the buried dielectric layer 110. Because the second recess RS2 of the buried dielectric layer 110 has a different size between the cell array region CAR and the peripheral circuit region PR, the conductive line 111 and the protection layer 113 may each have a different size between the cell array region CAR and the peripheral circuit region PR.

The conductive line 111 may include a conductive material, such as polysilicon, impurity-doped polysilicon, and metallic materials. The protection layer 113 may include one or more of silicon nitride and silicon oxynitride that contain nitrogen (N). When the conductive line 111 includes no metallic material, the formation of the protection layer 113 may be omitted.

A deposition process may be performed to form the conductive line 111 and the protection layer 113. The deposition process may include one or more of chemical vapor deposition (CVD), physical vapor deposition (PVD), and atomic layer deposition (ALD).

Thereafter, the dielectric pattern 115 may fill an upper portion of the second recess RS2. The dielectric pattern 115 may include the same material as that of the buried dielectric layer 110. After the formation of the dielectric pattern 115, a planarization process may be performed.

Referring back to FIGS. 3A and 3B, on the semiconductor substrate 100 of the cell array region CAR, there may be formed a word-line structure, first and second source/drain patterns SD1 and SD2, first and second interlayer dielectric layers 200 and 210, a bit line BL, a bit-line contact DC, storage contacts BC, and data storage patterns DSP, and the formation thereof may be the same as or similar to that discussed with reference to FIGS. 4A, 5A, 6A, 7A, 8A, and 9A.

On the semiconductor substrate 100 of the peripheral circuit region PR, there may be formed a peripheral transistor PTR including peripheral source/drain patterns PSD, a channel layer 131, and a gate pattern GP. A first interlayer dielectric layer 200 may cover the peripheral transistor PTR. The formation of the peripheral transistor PTR may be the same as or similar to that discussed with reference to FIGS. 4B, 5B, 6B, 7B, 8B, and 9B.

Differently from that discussed with reference to FIGS. 10A, 10B, 11A, and 11B, neither the conductive line 111 nor the protection layer 113 may be formed on the peripheral circuit region PR. In this case, the conductive line 111 and the protection layer 113 may be formed only on the cell array region CAR.

According to some embodiments of the present inventive concepts, a buried dielectric layer may bury a word line and a channel pattern of a semiconductor memory device. Therefore, cell transistor may be prevented from occurrence of leakage current.

According to some embodiments of the present inventive concepts, a conductive line may be included in the buried dielectric layer of the semiconductor memory device. A bias voltage may be applied through the conductive line to create a body effect only in a specific word line. Accordingly, it may be possible to minimize a capacitor leakage current resulting from an electric field of an adjacent word line.

While only detailed examples of the present inventive concepts have been particularly shown and described, it will be apparent to those skilled in the art that various changes in form and details may be made therein without departing from the spirit and scope of the inventive concepts, and it is reasonable that all differences related in the modification and application thereof will belong to the following claims.

Although the present invention has been described in connection with the embodiments of the present inventive concepts illustrated in the accompanying drawings, it will be understood to those skilled in the art that various changes and modifications may be made without departing from the technical spirit and essential feature of the present inventive concepts. It therefore will be understood that the embodiments described above are just illustrative but not limitative in all aspects.

What is claimed is:

1. A semiconductor memory device, comprising:
a substrate;
a buried dielectric layer on the substrate and providing a first recess that extends in a first direction;
a word line in the first recess of the buried dielectric layer;
first and second source/drain patterns on opposite sides of the word line;
a channel pattern between the word line and the first recess of the buried dielectric layer, the channel pattern being connected to the first and second source/drain patterns; and
a bit line electrically connected to the second source/drain pattern and extending in a second direction that intersects the first direction,
wherein the channel pattern includes vertical parts and a horizontal part connected to each other,
wherein the vertical parts are on opposite lateral surfaces of the word line, and
wherein the horizontal part is below the word line.

2. The semiconductor memory device of claim 1, wherein top surfaces of the vertical parts of the channel pattern are in contact with the first and second source/drain patterns.

3. The semiconductor memory device of claim 1, further comprising:
a gate dielectric pattern between the word line and the channel pattern.

4. The semiconductor memory device of claim 1, further comprising:
a gate capping pattern on the word line,
wherein a top surface of the gate capping pattern is coplanar with a top surface of the buried dielectric layer.

5. The semiconductor memory device of claim 1, wherein the first and second source/drain patterns are on the buried dielectric layer.

6. The semiconductor memory device of claim 1, wherein the first and second source/drain patterns are in the buried dielectric layer.

7. The semiconductor memory device of claim 1, wherein the word line is spaced apart in a vertical direction from the substrate.

8. The semiconductor memory device of claim 1, further comprising:
a conductive line in the buried dielectric layer and below the word line.

9. The semiconductor memory device of claim 8, further comprising a protection layer on the conductive line.

10. The semiconductor memory device of claim 8, wherein the conductive line is parallel to the word line and extends in the first direction.

11. The semiconductor memory device of claim 8, wherein, in the second direction, a width of the conductive line is the same as a width of the channel pattern.

12. A semiconductor memory device, comprising:
a substrate that includes a cell array region and a peripheral circuit region;
a buried dielectric layer on the substrate and including first recesses that extend in a first direction on the cell array region;
word lines in corresponding first recesses of the buried dielectric layer;
channel patterns between the buried dielectric layer and the word lines;
first and second source/drain patterns on opposite sides of each of the word lines;
bit lines that extend in a second direction intersecting the first direction on the first and second source/drain patterns;
bit-line contacts that connect the second source/drain patterns to the bit lines;
data storage patterns on the first source/drain patterns;
storage contacts that connect the data storage patterns to the first source/drain patterns; and
a peripheral transistor on the peripheral circuit region and on the buried dielectric layer,
wherein the channel patterns are in contact with the first and second source/drain patterns.

13. The semiconductor memory device of claim 12, wherein the peripheral transistor includes:
a channel layer on the buried dielectric layer; and
a gate pattern and peripheral source/drain patterns on the channel layer,
wherein the peripheral source/drain patterns are on opposite sides of the gate pattern.

14. The semiconductor memory device of claim 12, further comprising:
gate dielectric patterns between the channel patterns and the word lines; and
gate capping patterns on the word lines,
wherein a top surface of each of the gate capping patterns is coplanar with a top surface of the buried dielectric layer.

15. The semiconductor memory device of claim 12, further comprising conductive lines in the buried dielectric layer and vertically spaced apart from the word lines.

16. The semiconductor memory device of claim 15, further comprising:
protection layers and dielectric patterns on the conductive lines,
wherein the dielectric patterns are between the word lines and the protection layers.

17. A method of fabricating a semiconductor memory device, the method comprising:
preparing a substrate that includes a cell array region and a peripheral circuit region;
forming a buried dielectric layer on the substrate;
forming a recess by partially etching the buried dielectric layer on the cell array region;
forming, in the recess, a word-line structure that includes a word line, a channel pattern, and a gate dielectric pattern;
forming a channel layer on the buried dielectric layer on the peripheral circuit region;
forming a gate pattern on the channel layer;
forming first and second source/drain patterns on opposite sides of the word-line structure; and
forming peripheral source/drain patterns on opposite sides of the gate pattern,
wherein forming the first and second source/drain patterns and forming the peripheral source/drain patterns are performed at the same time.

18. The method of claim 17, wherein the gate dielectric pattern is between the channel pattern and the word line.

19. The method of claim 17, before forming the word-line structure, further comprising forming a conductive line in the buried dielectric layer.

20. The method of claim 19, before forming the word-line structure, further comprising forming a protection layer on the conductive line.
